(19) United States
(12) Patent Application Publication
(10) Pub. No.: US 2025/0284993 A1
(43) Pub. Date: Sep. 11, 2025

(54) QUANTUM BIT ARRAY CHIP AND QUANTUM COMPUTER

(71) Applicant: Hitachi, Ltd., Tokyo (JP)

(72) Inventors: Tomonori SEKIGUCHI, Tokyo (JP); Takeru UTSUGI, Tokyo (JP); Go SHINKAI, Tokyo (JP)

(21) Appl. No.: 18/861,695

(22) PCT Filed: Jan. 19, 2023
(86) PCT No.: PCT/JP2023/001426

§ 371 Date: Oct. 30, 2024

(30) Foreign Application Priority Data
May 24, 2022 (JP) 2022-084878

(51) Int. Cl. G06N 10/40; B82Y 10/00; H10N 60/10

(52) U.S. Cl. CPC G06N 10/40; H10N 60/11; H10N 60/128; B82Y 10/00

(57) ABSTRACT

A quantum bit array chip includes first gate electrodes that are arranged on an insulating layer and trap electrons in a predetermined spin state in a semiconductor layer by applying a voltage, second gate electrodes arranged alternately with the first gate electrodes to cause a current for forming a magnetic field acting on the electrons to flow in an extending direction of the first gate electrodes when the spin state of the electrons is changed, and a third gate electrode. The third gate electrode has the same resistance as the second gate electrodes, and when the spin state of electrons trapped in the first gate electrodes is changed, control is performed to cause a current to flow to the third gate electrode, and after the current is stabilized, stop the flowing of the current to the third gate electrode and cause a current to flow to the second gate electrodes.

### TECHNICAL FIELD

The present invention relates to a quantum bit array chip and a quantum computer in which quantum bits are arranged and integrated on an array in order to perform quantum computing.

### BACKGROUND ART

In recent years, quantum computers have attracted attention. The miniaturization and performance of semiconductor elements that have supported the progress of computers have been limited, and it has become difficult to significantly improve the performance of conventional classical computers. Quantum computers are one of attempts to overcome this limit with new computational principles and devices. Currently, hardware development is actively performed for realizing a quantum computer, and a system such as a superconducting/ion trap/silicon type has been proposed as a quantum bit which is an arithmetic element of a core part of the quantum computer.

The overall configuration of a silicon quantum computer 1000 is illustrated in FIG. 1. The quantum bits Qubit102, which are quantum computation devices, are arranged in an array and mounted on a quantum bit array chip QBA101 manufactured as a silicon chip. In the QBA101, quantum bit control for quantum computation and sensing of quantum information of a computation result are performed. A cryogenic analog control chip CAC103 supplies a quantum operation pattern, an operation timing, a bias voltage, and an RF signal to the QBA101. The CAC103 is controlled by a host computer and a digital control chip CDC104 having a bridge function, and receives the computation result performed by the QBA101.

In order to stably operate the quantum bits, the QBA101 is disposed in a dilution refrigerator DR and operated at a cryogenic temperature of about 0.1 K. The CAC103 that controls this is disposed in an environment of about 4 K in the dilution refrigerator DR. The host computer and the CDC104 are operated at room temperature.

FIG. 2A illustrates a cross-sectional view of a Qubit array mounted on the QBA. In this QBA, a spin S of a single electron confined in a potential barrier PB formed in the Si channel C of a MOS structure is used as the Qubit. FIG. 2A(a) illustrates a state in which electrons are trapped immediately below a quantum dot control gate XQ201 by increasing a voltage of the quantum dot control gate XQ201 and decreasing a voltage of an interaction control gate XJ202. Qubit computation is controlled by radiating a radio frequency RF signal as illustrated in FIG. 2B(b). A magnetic field B is applied to Qubit in the array, and a frequency f_{S} of the precession motion is set to 20.01 GHz for a selected bit and 20 GHz for an unselected bit. When the entire array is irradiated with an RF signal having a frequency of 20.01 GHz, spin of only a select bit whose frequency of precession matches that of the RF is rotated, and the quantum computation can be performed.

In the Qubit array, Qubits are two-dimensionally arranged in the X direction and the Y direction as illustrated in FIG. 3. A plurality of quantum dot control gate lines XQ2022 and interaction control gates XJ2021 arranged side by side in the X direction are formed as gate wires of a first layer of the MOS structure, and a plurality of quantum dot control gate lines YQ2032 and interaction control gates YJ2031 arranged side by side in the Y direction are formed as gate wires of a second layer. In this drawing, in order to make the drawing easily viewable, a view in which a space between the gate wire of the first layer and the silicon channel C is widened in the Z direction is illustrated. By adopting such an array structure, large-scale integration of quantum bits realized, while suppressing an increase in the total number of wires.

As a technique using such a quantum bit, for example, a technique described in PTL 1 is disclosed.

### CITATION LIST

### Patent Literature

PTL 1: WO2021/251175

### SUMMARY OF INVENTION

### Technical Problem

A problem in the conventional technique represented by PTL 1 will be specifically described using a circuit diagram of a Qubit array as illustrated in FIG. 4. In this circuit diagram, a preprocessing array 402 and a postprocessing array 403 are arranged on both sides of a central arithmetic array 401. In the array, a quantum dot control gate MOS (gate connected to XQ or YQ) and an interaction control gate MOS (gate connected to XJ) are alternately arranged. A silicon channel of an SOI structure is connected in the X direction, and enables movement and interaction of electrons between Qubits via a transfer gate. In addition, an interaction control gate MOS (a gate is connected to YJ) that connects the silicon channels in the Y direction is arranged, and the movement and interaction of the electrons are also possible in the Y direction.

In the arithmetic array 401, 128 MOSs used as Qubit are arranged in 8 rows×16 columns. The preprocessing array 402 and the postprocessing array 403 also have 2 and 4 rows of MOSs for quantum dots, respectively. The silicon channel is commonly connected to a reservoir terminal Nres on one side in both the X direction and the Y direction at an array end, and is separated as a DOE/DOS terminal on one side. Although not illustrated as the wire, an RF signal RFQB is arranged on the present array by multilayer wire.

First, a first problem to be solved by the present invention will be described. In the present chip, there are spin rotation (Rx) around the X-axis and spin rotation (Ry) around the Y-axis computations as computations for one Qubit. These rotate the orientation of the spin holding Qubit quantum information by 90° around the X-axis and Y-axis of the Bloch sphere, respectively.

As an example of control at the time of performing the Rx/Ry computation, control by a dynamic resonance frequency changing method is illustrated in FIGS. 5A and 5B. FIG. 5B(b) illustrates an example of an operation waveform when Qubit qb00 is operated in the array circuit diagram of FIG. 5A(a). First, by applying a static magnetic field to the entire chip, the resonance frequency of the precession of spins of electrons in all the quantum bits is set to 20 GHz.

When the computation is performed, a voltage of V_{L1}-V_{L2} is applied between terminals XJN₁ and XJS₁ and between the terminals XJN₂ and XJS₂, and a current of 20 uA is applied from XJS₁ to XJN₁ and from XJN₂ to XJS₂. Further, a voltage of V_{L3} to V_{L4} is applied between terminals YJW₀ and YJE₀ and between terminals YJW₁ and YJW₁, and a current of 1 mA is applied from YJW₀ to YJE₀ and from YJE₁ to YJW₁. A local magnetic field generated by the current increases a resonance frequency f_{qb00} of the spin precession of electrons in qb00 from 20 GHz in the standby state to 20.01 GHz. In this state, when the RF signal RFQB of 20.01 GHz is applied to the entire chip for a time of ¼ of the period t_{RB} of the Rabbit vibration, only the electron spin in qb00 having the same resonance frequency can be selectively rotated by 90°. In this case, when the phase of the RF signal is matched with the phase of the precession of the spin, the rotation around the X axis is performed, and when the phase is differentiated by 90°, the rotation around the Y axis can be realized. Finally, the voltage applied between the terminals XJN₁ and XJS₁, between XJN₂ and XJS₂, between YJW₀ and YJE₀, and between YJW₁ and YJE₁ is inverted, f_{qb00} is set to 19.99 GHz, and then the same time is waited to compensate for the phase change of the precession of the spin.

FIG. 6 illustrates a relationship among phases of a reference signal, an RF signal, and a spin of 20 GHz by performing this computation. When the frequency f_{RF} of the RF wave is changed from 20 GHz to 20.01 GHz at time 0 at t=0, a phase difference φ_{RF} between the RF wave and the reference signal increases at a rate of 0.5 ps per 1 ns. This frequency switching is done inside the CAC and can be implemented very quickly.

Meanwhile, in order to increase the frequency f_{S} of the spin from 20 GHz to 20.01 GHz by supplying a current to Qubit, in order to change the current supplied from the CAC to the QBA, a rise time tr of the change increases to the ns level. Since a phase difference φ_{S} between the spin and the reference signal becomes 20.01 GHz after t=t_{R}, the frequency of the spin increases at 0.5 ps per 1 ns similarly to RF. However, since the frequency does not reach 20.01 GHz between t=0 and t=t_{R}, the phase change of φ_{S} becomes smaller than that. Therefore, the phase difference between RF and spin after t_{R} becomes φ_{RF0}-φ_{S0} using the phase differences φ_{RF0} and φ_{S0} from the respective reference signals at t=t_{R}.

In order to sufficiently maintain the fidelity of the quantum computation, that is, the accuracy of the computation, it is necessary to sufficiently reduce the phase difference between the RF wave and the spin. Assuming that f_{S} changes linearly, in order to keep φ_{RF0}-φ_{S0} equal to or less than 1 ps, which is 2% of the RF cycle 50 ps, the rise time of the signal needs to be 4 ns or less. The waveform at the time of the transition of the current is expected to change depending on the control circuit, but it is necessary to keep the transition time of the signal at several ns or less in order to sufficiently increase the fidelity.

FIG. 7A(a) illustrates a current supply path from the CAC to the Qubit array in the QBA. Since the CAC is in the 4K chamber of the dilution refrigerator and the QBA is in the 100 mK chamber, they are connected by several meters of coaxial cables or twisted cables. Therefore, the cable that supplies the voltages V_{L3} and V_{L4} from the voltage buffer in the CAC has a parasitic resistance R_{W} of several tens Ω order and a parasitic capacitance C_{W} of several hundred pF.

In the QBA, a quantum bit control gate (here, a gate that connects YJW₀ and YJE₀, which are one of the gates, is illustrated) in a Qubit array has a parasitic resistance R_{W}, and current switches SW₀ and SE₀ that control a current flowing therethrough also have a parasitic resistance R_{S}.

FIG. 7B(b) illustrates operation waveforms. First, in a time zone (1), the two voltage buffers in the CAC supply the voltages V_{L3} and V_{L4} to the QBA, but since all the switches are turned off, voltage supply nodes NW and NE are charged to the voltages V_{L3} and V_{L4}. Subsequently, in a time zone (2), the current switches SW₀ and SE₀ are turned on in order to cause a current to flow between the gates YJW₀ and YJE₀ of the quantum bits. When the current flows through a cable resistance R_{W}, an on-resistance R_{S} of the switch, and a gate wire resistance R_{Q} of the Qubit array, the potentials of NH and NL change to V_{L3I} and V_{L4I}, respectively, and a stable current I₀ of 1 mA starts to flow. Thereafter, the RF signal is emitted, and the rotation around the X axis/the Y axis is computed. Finally, in a time zone (3), the switch is turned off to return to the standby state.

However, in the case of such an operation, since the parasitic capacitance C_{W} of the cable is large, a time t_{R0} until the potential is stabilized and the current value of the Qubit array is stabilized to 1 mA sufficient for the frequency change is required to be about 10 ns. Therefore, it is difficult to keep the fidelity sufficiently high in this method.

A first problem to be solved by the present invention is to increase the transition time of the current supplied to the quantum bit in order to enhance the fidelity of the computation of the spin rotation around the X axis and the spin rotation around the Y axis. An object of one aspect of the present invention is to provide a quantum bit array chip and a quantum computer for solving the problem.

Next, a second problem to be solved by the present invention will be described. As illustrated in FIG. 4, the Qubit array has 100 or more control lines. When the quantum computation is performed, it is necessary to apply about eight types of bias voltages to the terminals of the control lines and to switch over time. Therefore, when the connection between the control terminal and the bias voltage is simply switched by a signal input from the outside of the QBA, the number of necessary signals exceeds 800. Meanwhile, the number of input/output terminals of the QBA is desirably suppressed to about 100 to 200 from the viewpoint of the chip size.

A second problem to be solved by the present invention is to realize control capable of switching a plurality of bias voltages to a large number of quantum bit arrays, while reducing the number of external input terminals of the QBA. An object of one aspect of the present invention is to provide a quantum bit array chip and a quantum computer for solving the problem.

### Solution to Problem

A quantum bit array chip according to an aspect of the present invention includes: a semiconductor layer; an insulating layer disposed on the semiconductor layer; a plurality of first gate electrodes that are arranged on the insulating layer and trap electrons in a predetermined spin state in the semiconductor layer by applying a voltage; a plurality of second gate electrodes arranged alternately with the first gate electrodes adjacent to the first gate electrodes in order to cause a current for forming a magnetic field acting on the electrons to flow in an extending direction of the first gate electrodes when the spin state of the electrons is changed; and a third gate electrode having substantially the same resistance as the second gate electrodes, in which when the spin state of electrons trapped in the first gate electrodes is changed, control is performed to cause a current to flow to the third gate electrode, and after the current is stabilized, stop the flowing of the current to the third gate electrode and cause a current to flow to the second gate electrodes.

In addition, a quantum bit array chip according to an aspect of the present invention includes: a semiconductor layer; an insulating layer disposed on the semiconductor layer; a plurality of first gate electrodes that are arranged on the insulating layer and trap electrons in a predetermined spin state in the semiconductor layer by applying a voltage; a plurality of second gate electrodes arranged alternately with the first gate electrodes adjacent to the first gate electrodes; and when the spin state of the electrons is changed, a magnetic field acting on the electrons being strengthened by causing currents in different directions to flow to a first direction second gate electrode and a second direction second gate electrode, which are two second gate electrodes adjacent to the first gate electrode, a plurality of third gate electrodes having substantially the same resistance as the second gate electrodes, in which when the spin state of the electrons trapped in the first gate electrodes is changed, control is performed to cause current to flow to a first direction third gate electrode and a second direction third gate electrode, which are the two third gate electrodes, and after the current is stabilized, stop the flowing of the current to the third gate electrode and cause currents in different directions to flow to the two first direction second gate electrode and second direction second gate electrode.

Further, a quantum bit computer according to an aspect of the present invention includes: a quantum bit array including a semiconductor layer, an insulating layer disposed on the semiconductor layer, a plurality of first gate electrodes that are disposed on the insulating layer and trap electrons in a predetermined spin state in the semiconductor layer by applying a voltage, and a plurality of second gate electrodes arranged alternately with the first gate electrodes adjacent to the first gate electrodes in order to cause a current for forming a magnetic field acting on the electrons to flow in an extending direction of the first gate electrodes when the spin state of the electrons is changed; a first chip on which the quantum bit array is mounted; a second chip that controls the first chip; and a cable that connects the first chip and the second chip, in which when a current is supplied from a voltage output buffer of the second chip to the second gate electrode of the quantum bit array included in the first chip, the voltage output buffer outputs a first voltage in a standby state, outputs a second voltage at an initial stage of supplying the current, and outputs a third voltage that is substantially the same voltage as the first voltage when the current is stabilized.

In addition, a quantum bit array chip according to an aspect of the present invention includes a semiconductor layer; an insulating layer disposed on the semiconductor layer; a plurality of gate electrodes that are disposed on the insulating layer and trap electrons in a predetermined spin state in the semiconductor layer by applying a voltage; a switch matrix that controls a voltage output to the gate electrodes according to a voltage supplied from an external chip; a bias voltage supply terminal that outputs the controlled voltage to the gate electrodes; and a register for generating an array control signal for the quantum bit array chip, in which a bias voltage is supplied to the gate electrode from a plurality of the bias voltage supply terminals via the switch matrix, and a voltage to be supplied to each of the gate electrodes is selectable, and the register stores the supplied bias voltage and the gate electrode to which the bias voltage is supplied in association with each other.

### Advantageous Effects of Invention

According to one aspect of the present invention, it is possible to switch a resonance frequency of a quantum bit at high speed, and it is possible to maintain high fidelity when computing rotation around the X axis and rotation around the Y axis, which are types of quantum computations.

In addition, according to one aspect of the present invention, it is possible to reduce the number of input terminals of the chip and to speed up the processing, while making it possible to supply a plurality of bias voltages to a large number of quantum bit control lines. Problems, configurations, and effects other than those described above will be clarified by the following description of embodiments for carrying out the invention.

### BRIEF DESCRIPTION OF DRAWINGS

FIG. 1 is a diagram illustrating a silicon quantum computer.

FIG. 2A is a diagram illustrating a silicon quantum bit structure.

FIG. 2B is a diagram illustrating a quantum computation system in the silicon quantum bit structure illustrated in FIG. 2A.

FIG. 3 is a diagram illustrating a silicon quantum bit array structure.

FIG. 4 is a circuit diagram of a quantum bit array

FIG. 5A is a circuit diagram of a dynamic resonance frequency changing method.

FIG. 5B is an operation waveform in the circuit diagram of the dynamic resonance frequency changing method illustrated in FIG. 5A.

FIG. 6 is a diagram illustrating a phase of spin precession.

FIG. 7A is a circuit diagram of a current supply path to a conventional QBA.

FIG. 7B is an operation waveform in the circuit diagram of the current supply path the conventional QBA illustrated in FIG. 7A.

FIG. 8A is a circuit diagram of a current supply path to a first QBA of the present embodiment.

FIG. 8B is an operation waveform in a circuit diagram of the current supply path to the first QBA of the present embodiment illustrated in FIG. 8A.

FIG. 9A is a circuit diagram of a current supply path to a second QBA of the present embodiment.

FIG. 9B is an operation waveform in the circuit diagram of the current supply path to the second QBA of the present embodiment.

FIG. 10A is a diagram illustrating a result of circuit simulation.

FIG. 10B is a diagram illustrating a result of circuit simulation.

FIG. 11A is a circuit diagram of a current supply path to a third QBA of the present embodiment.

FIG. 11B is an operation waveform in a circuit diagram of a current supply path to a third QBA of the present embodiment.

FIG. 12 is a diagram illustrating a configuration of a QBA.

FIG. 13 is a diagram illustrating an interface system between CAC and QBA.

FIG. 14 is a diagram illustrating a block configuration of a switch control register and a switch matrix of the present embodiment.

FIG. 15 is a diagram illustrating a configuration of the switch control register of the present embodiment.

FIG. 16 is a diagram illustrating a silicon quantum bit structure in the present embodiment.

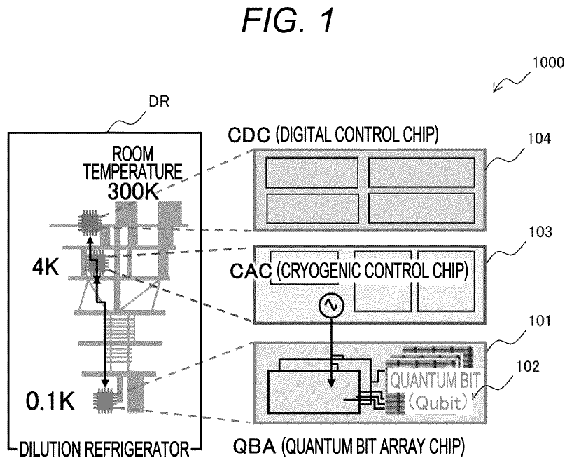

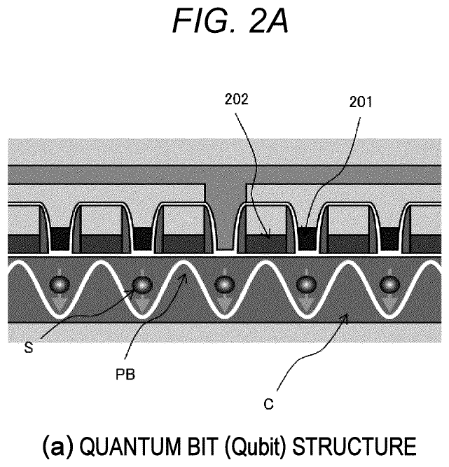

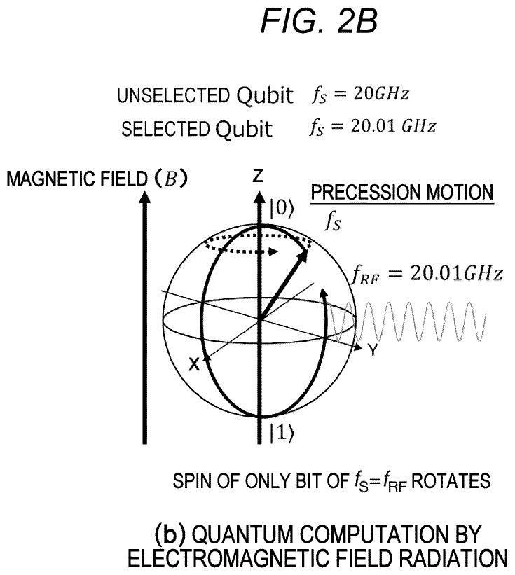

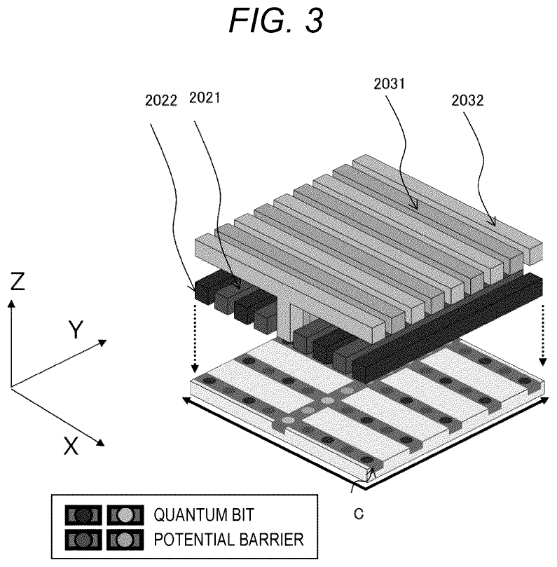

### DESCRIPTION OF EMBODIMENTS

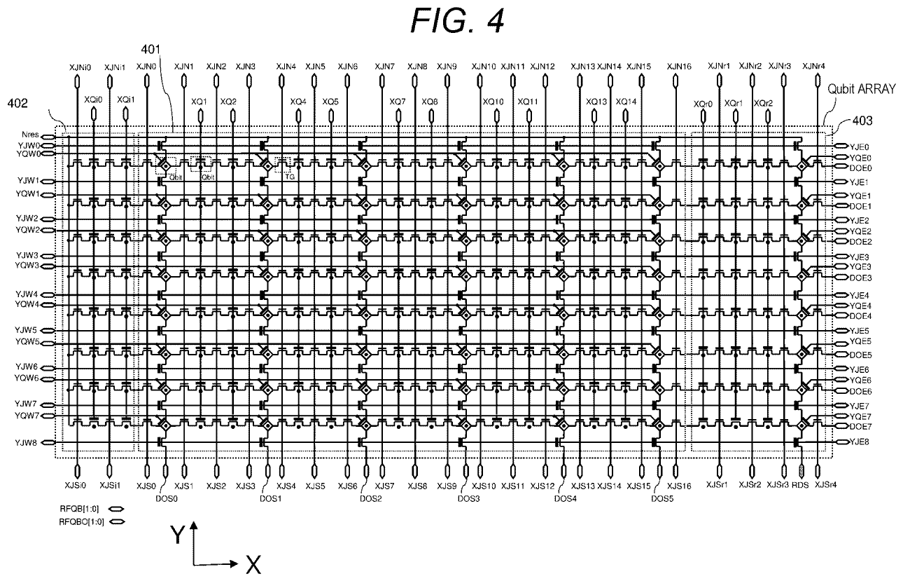

Hereinafter, each embodiment will be described with reference to the drawings. In each of the following embodiments, a QBA having a Qubit array in which a quantum dot control gate MOS (gate connected to XQ or YQ) and an interaction control gate MOS (gate connected to XJ) as illustrated in FIG. 4 are alternately arranged will be described.

### First Embodiment

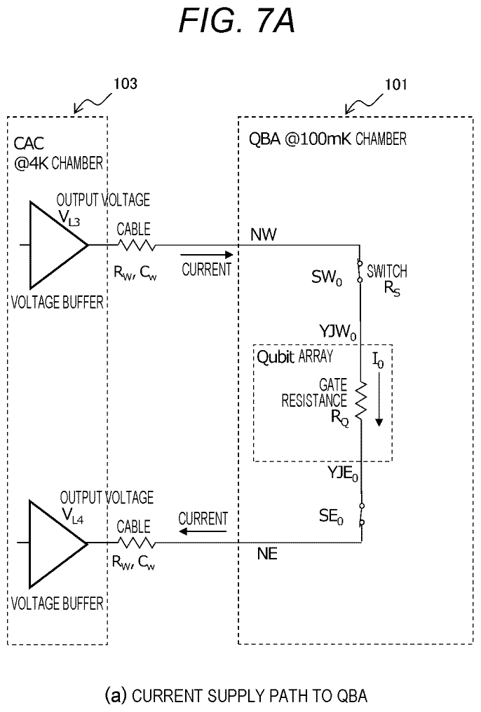

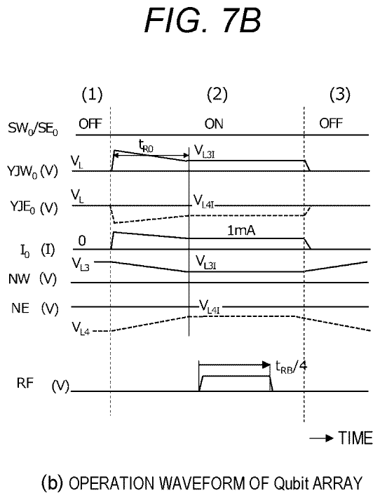

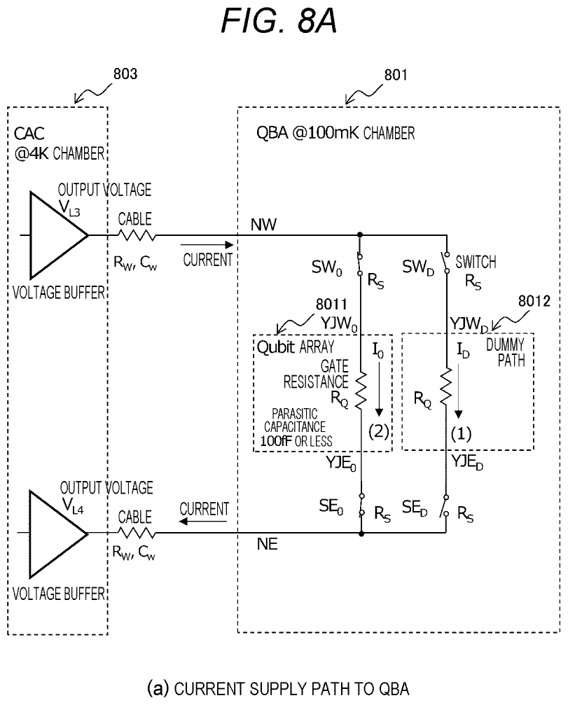

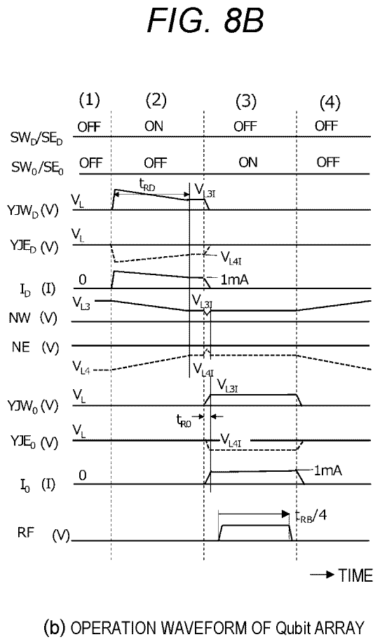

A first embodiment of the present invention is illustrated in FIGS. 8A and 8B. FIG. 8A(a) illustrates current supply paths from the CAC to the Qubit array in the QBA of the present embodiment. Similar to FIG. 7A, CAC803 is in the 4K chamber of the dilution refrigerator and QBA801 is in the 100 mK chamber, so both are connected by several meters of coaxial or twisted cable. Therefore, the cable that supplies the voltages V_{L3} and V_{L4} from the voltage buffer of the CAC has a parasitic resistance R_{W} of several tens Ω order and a parasitic capacitance C_{W} of several hundred pF.

In the QBA, a quantum bit control gate (here, a gate that connects YJW₀ and YJE₀, which are one of the gates, is illustrated) in a Qubit array has a parasitic resistance R_{Q}, and current switches SW₀ and SE₀ that control a current flowing therethrough also have a parasitic resistance R_{S}.

In the present embodiment, a dummy path 8012 having the same structure as the Qubit array 8011 is provided. The dummy path 8012 includes a dummy quantum bit control gate that connects the terminals YJW_{D} and YJE_{D}. This gate has the same parasitic resistance R_{Q} as that of the Qubit array 8011, and the current switches SW_{D} and SE_{D} that control the current also have the same parasitic resistance R_{S} as that for the quantum bit array. Note that this dummy path may use a specific quantum bit control gate in the Qubit array, or may be created physically separately.

FIG. 8B(b) illustrates an operation waveform at the time of computation using the current dummy path of the present embodiment. First, in a time zone (1), the two voltage buffers in the CAC803 supply the voltages V_{L3} and V_{L4} to the QBA801, but since all the switches are turned off, the voltage supply nodes NW and NE are charged in the voltages V_{L3} and V_{L4}.

In a time zone (2), before a current flows between the gates YJW₀ and YJE₀ of the Qubit array 8011, the current switches SW_{D} and SE_{D} are turned on to flow a current to the gates YJW_{D} to YJE_{D} of the dummy path 8012. Then, the current flows through the cable resistance R_{W}, the on-resistance R_{S} of the switch, and the gate wire resistance R_{Q} of the Qubit array, whereby the potentials of the voltage supply nodes NW and NE change to VL_{3I} and VL_{4I}, respectively. In this case, since the parasitic capacitance C_{W} of the cable is as large as about 300 pF, a time t_{RD} until the potential is stabilized and the current value of the dummy path is stabilized to 1 mA is required to be 10 ns or more.

Subsequently, in a time zone (3), the switch of the dummy path 8012 is turned off, and the current switches SW₀ and SE₀ of a selection Qubit array 8011 are turned on. Then, the current from the voltage buffer of the CAC803 flows from the voltage supply node NW to the voltage supply node NE via the Qubit array, but since the voltage supply nodes NW and NE are already stable at the voltages VL_{3I} and VL_{4I}, the current value is stabilized at 1 mA in a short time of about t_{R0}=1 ns. Thereafter, the RF signal is emitted, the rotation around the X axis/Y axis is computed, and finally, the current switch is turned off in the time zone of (4) to return to the standby state.

Therefore, when the present embodiment is used, the current applied to the quantum bit can be raised at a high speed, and the resonance frequency of the quantum bit can be switched at a high speed, so that it is possible to maintain high fidelity when performing the Rx/Ry computation. As described above, in order to realize high-speed current supply to the Qubit array, which is the first problem, the inventors devise a current dummy path method, provide a dummy path having the same structure as that of the Qubit array adjacent to the Qubit array, and initially supply a current to the dummy path, thereby charging the parasitic capacitance such as the CAC-QBA connection cable to the final voltage in advance. Then, by switching the current path to the gate of the selected quantum bit in the Qubit array in this state, the transition time of the current can be shortened. As a result, it is possible to provide a QBA having higher computation accuracy than before and a quantum computer including the QBA.

### Second Embodiment

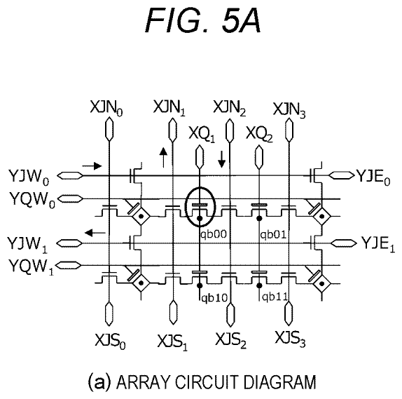

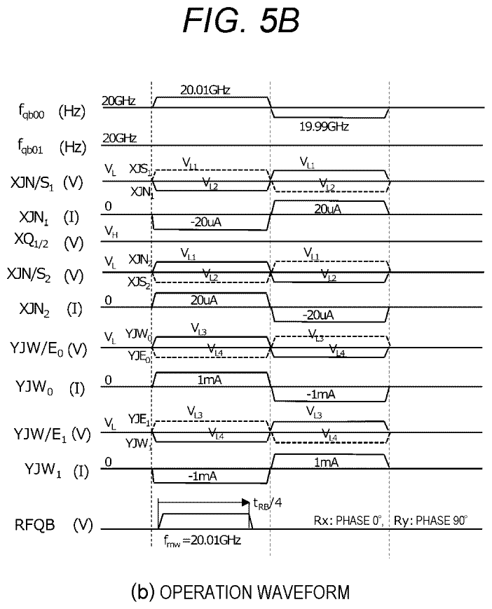

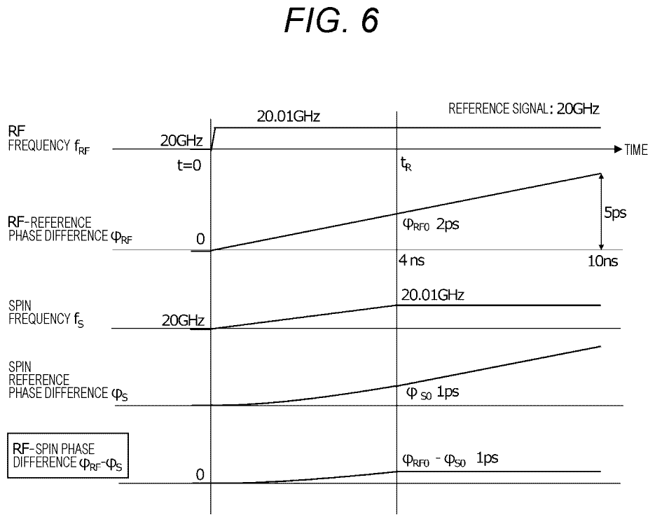

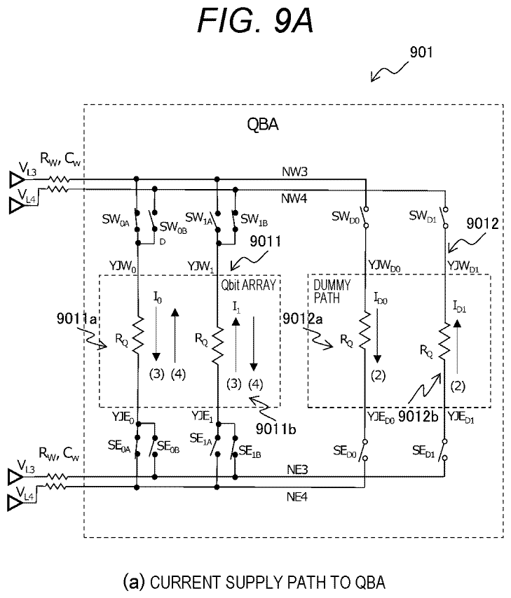

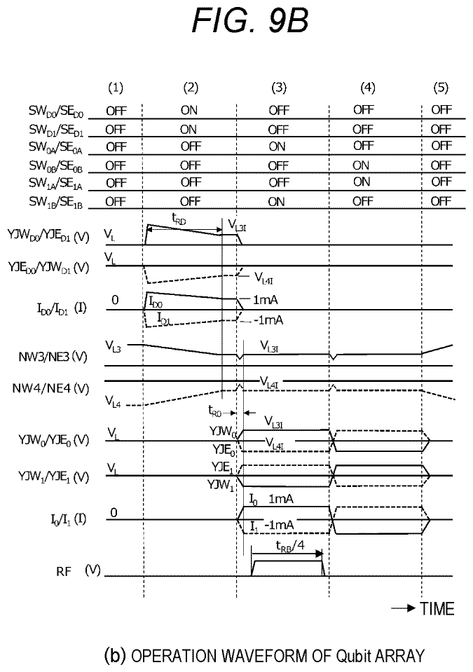

A second embodiment of the present invention is illustrated in FIG. 9. In the present embodiment, a case is illustrated in which a current dummy path is applied in a drive system in which a current facing an adjacent gate wire in an opposite direction is applied as illustrated in FIG. 5 to strengthen a magnetic field when the local magnetic field of the quantum bit is generated. FIG. 9A(a) illustrates current supply paths from the CAC to the Qubit array in the present embodiment QBA901. In this drawing, the CAC is omitted, and only the internal voltage buffer is illustrated. Similar to FIGS. 7A, 7B, 8A, and 8B, the CAC is in the 4K chamber of the dilution refrigerator and QBA901 is in the 100 mK chamber, so both are connected by several meters of coaxial or twisted cable. Therefore, the cable that supplies the voltages V_{L3} and V_{L4} from the voltage buffer of the CAC has a parasitic resistance R_{W} of several tens Ω order and a parasitic capacitance C_{W} of several hundred pF.

In the QBA901, an example of a two-line system including a gate 9011a connecting YJW₀ and YJE₀, which are two quantum bit control gates 9011 in the Qubit array, and a gate 9011b connecting YJW₁ and YJE₁ is illustrated. These have a parasitic resistance R_{Q}. Current switches SW_{0A} and SW_{0B} are connected to an end YJW₀ of the gate wire, and are connected to voltage supply nodes NW3 and NW4 connected to voltage buffers for supplying voltages VL₃ and VL₄ in the CAC via cables. Similarly, the switches SW_{1A} and SW_{1B} are connected to the end YJW₁, and are connected to the voltage supply nodes NW3 and NW4. In addition, current switches SE_{0A} and SE_{0B} are connected to an end YJE₀ of the gate wire, and are connected to voltage supply nodes NE3 and NE4 connected to voltage buffers for supplying voltages VL₄ and VL₃ of CAC via cables. Similarly, the current switches SE_{1A} and SE_{1B} are connected to the end YJE₁, and are connected to the voltage supply nodes NE4 and NE3. These switches have parasitic resistances R_{S}.

In the present embodiment, a dummy path 9012 having the same structure as the Qubit array is further provided. The dummy path 9012 includes a quantum bit control gate 9012a that connects an end YJW_{D0} and an end YJE_{D0}, and a dummy quantum bit control gate 9012b that connects ends YJW_{D1} and YJE_{D1}. These have the same parasitic resistance R_{Q} as the Qubit array.

A current switch SW_{D0} is connected to the end YJW_{D0} of the gate wire, and is connected to the voltage supply node NW3. A current switch SW_{D1} is connected to the YJW_{D1}, and is connected to a voltage supply node NW4. Similarly, a current switch SE_{D0} is connected to an end YJE_{D0} of the gate wire, and is connected to the voltage supply node NE4. A current switch SE_{D1} is connected to the YJE_{D1}, and is connected to the voltage supply node NE3. These switches also have the same parasitic resistance R_{S} as for the quantum bit array. This dummy path may use a specific quantum bit control gate in the Qubit array, or may be created physically separately.

FIG. 9B(b) illustrates an operation waveform using the current dummy path of the present embodiment. First, in the time zone (1), the voltage buffer in the CAC supplies the voltages V_{L3} and V_{L4} to the QBA, but since all the switches are turned off, the voltage supply node NW3/NE3 is charged to the V_{L3}, and the voltage supply node NW4/NE4 is charged to the V_{L4}. In the time zone (2), before the current flows to the quantum bit control gate 9011 of the Qubit array, the switches SW_{D0}, SE_{D0}, SW_{D1}, and SE_{D1} are turned on to flow the current to the dummy path 9012. Then, the currents I_{D0} and I_{D1} flow in the directions indicated by arrows in the drawing in the two dummy paths, and flow through the cable resistance R_{W}, the on-resistance R_{S} of the analog switch, and the gate wire resistance R_{Q} of the Qubit array, so that the potential of the voltage supply nodes NW3 and NE3 changes to V_{L3I}, and the potential of the voltage supply nodes NW4 and NE4 changes to V_{L4I}. In this case, since the parasitic capacitance C_{W} of the cable is as large as about 300 pF, a time t_{RD} until the potential is stabilized and the current value of the dummy path is stabilized to 1 mA is required to be 10 ns or more.

Subsequently, in the time zone (3), the switch of the dummy path 9012 is turned off, and the current switches SW_{0A}, SE_{0A}, SW_{1B}, and SE_{1B} of the selection Qubit array are turned on. Then, the current from the voltage buffer of the CAC flows from the voltage supply nodes NW3 and NE3 to the voltage supply nodes NE4 and NW4 via the Qubit array, but since these terminals are already stable at the voltages VL_{3I} and VL_{4I}, the currents I₀ and I₁ indicated by the arrow of (3) in the drawing are stable at 1 mA in a short time of about t_{R0}=1 ns. Thereafter, the RF signal is emitted, and the rotation around the X axis/the Y axis is computed.

Further, in the time zone (4), the current switches SW_{0A}, SE_{0A}, SW_{1B}, and SE_{1B} of the selection Qubit array are turned off, and the current switches SW_{0B}, SE_{0B}, SW_{1A}, and SE_{1A} of the selection Qubit array are turned on. Then, the directions of the currents I₀ and I₁ from the voltage buffer of the CAC are reversed and flow from the voltage supply nodes NW3 and NE3 to the voltage supply nodes NE4 and NW4 via the Qubit array. However, since these terminals are already stable at the voltages VL_{3I} and VL_{4I}, the current values I₀ and I₁ are stable at 1 mA in a short time of about t_{R0}=1 ns. By weakening the magnetic field of the selected quantum bit with this current and lowering the frequency of the precession motion of the spin to 19.99 GHz, the phase advanced from the reference signal due to the increase of the same frequency to 20.01 GHz in the period (3) can be returned to the original. Finally, in the time zone (5), the current switch is turned off to return to the standby state.

Therefore, when the present embodiment is used, the resonance frequency of the quantum bit can be switched at high speed, and the fidelity at the time of performing the rotation computation about the X axis/the Y axis can be maintained high. As a result, it is possible to provide a QBA having higher computation accuracy than before and a quantum computer including the QBA. In addition, even in a case where phase compensation of spin is performed by inverting the current flowing through the Qubit array, this method can be applied.

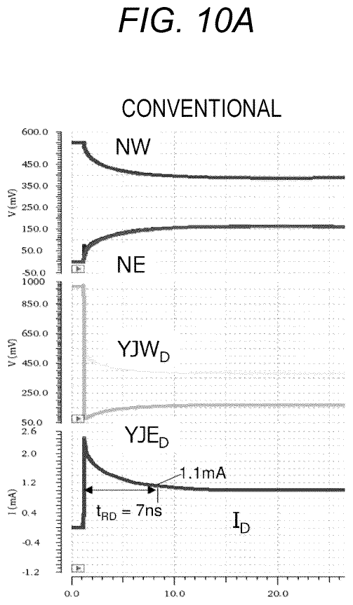

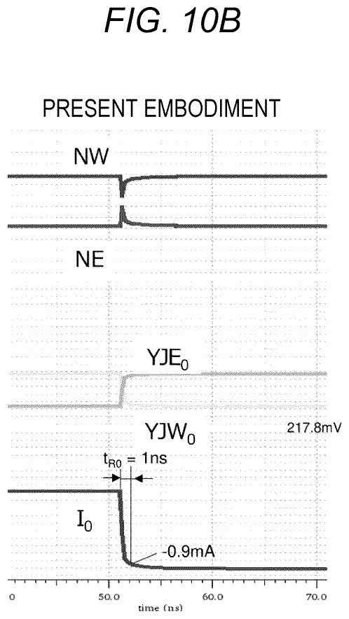

In order to confirm the effect of this method, the results of the circuit simulation are illustrated in FIGS. 10A and 10B. In the conventional method or the dummy path illustrated in FIG. 10A, the voltages of the voltage supply nodes NW and NE are stabilized after the current starts to flow, and 7 ns are required until the current value reaches 1.1 mA within an error 10% of 1 mA. Meanwhile, in the present embodiment illustrated in FIG. 10B, since the voltage supply nodes NW and NE are stable from the beginning, the time required to switch the direction of the current and change the current to −0.9 mA is significantly increased to 1 ns.

### Third Embodiment

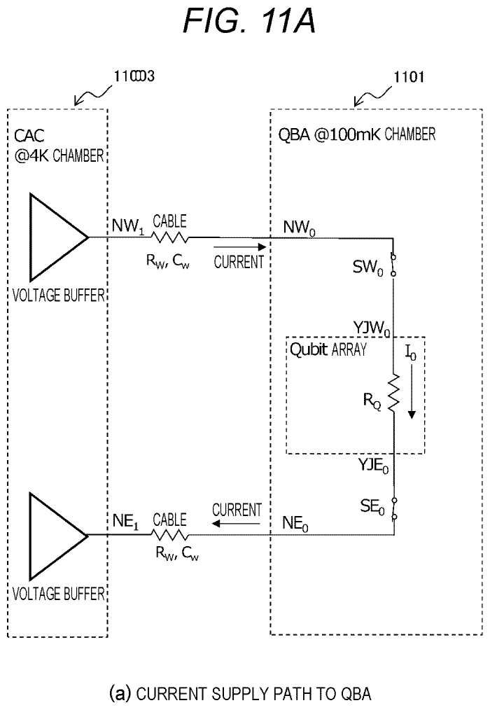

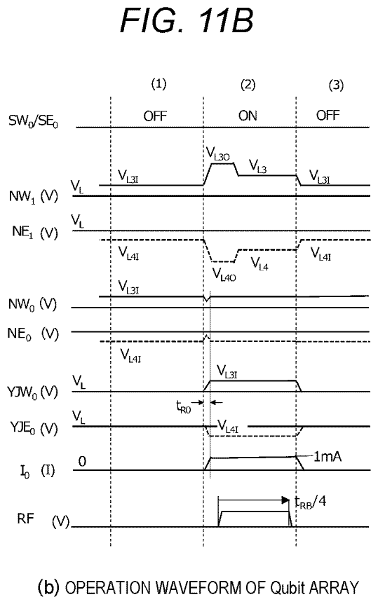

A third embodiment of the present invention is illustrated in FIGS. 11A and 11B. FIG. 11A(a) illustrates current supply paths from the CAC to the Qubit array in the QBA of the present embodiment. Similar to FIGS. 7A and 7B, the CAC is in the 4K chamber of the dilution refrigerator and the QBA is in the 100 mK chamber, so both are connected by several meters of coaxial or twisted cable. Therefore, the cable that supplies the voltages V_{L3} and V_{L4} from the voltage buffer of the CAC has a parasitic resistance R_{W} of several tens Ω order and a parasitic capacitance C_{W} of several hundred pF. In the QBA1101, a quantum bit control gate (here, a gate that connects YJW₀ and YJE₀, which are one of the gates, is illustrated) in a Qubit array has a parasitic resistance R_{Q}, and current switches SW₀ and SE₀ that control a current flowing therethrough also have a parasitic resistance R_{S}.

FIG. 11(B)(b) illustrates an operation waveform of the driving method of the present embodiment. First, in the time zone (1), the two voltage buffers in the CAC supply the voltages V_{L31} and V_{L4I} to the QBA. These voltages are stable voltages of the voltage supply nodes NW and NE in the QBA when the current is stabilized at 1 mA in the first embodiment. Since all the switches are turned off, the output buffer end NW₁ and the voltage supply node NW₀ of the cable are charged in the V_{L3I}, and the output buffer end NE₁ and the voltage supply node NE₀ of the cable are charged in the V_{L4I}.

In the time zone (2), the current switches SW₀ and SE₀ are turned on in order to cause a current to flow between the gates YJW₀ and YJE₀ of the Qubit array. Further, the voltage buffer connected to the output buffer end NW₁ overdrives with the voltage V_{L3O} higher than the voltage V_{L3} for a certain period of time, and then outputs V_{L3}. Similarly, the voltage buffer connected to the output buffer end NE₁ overdrives with a voltage V_{L4O} lower than the voltage V_{L4} for a certain period of time, and then outputs V_{L4}. By this overdrive operation, potential changes due to charging and discharging of the cable can be canceled and the voltage supply nodes NW₀ and NE₀ can be held in V_{L3I} and V_{L4I}, so that the current I₀ can be output at high speed. Thereafter, the RF signal is emitted, and the rotation around the X axis/the Y axis is computed. Finally, in the time zone (3), the current switch is turned off to return to the standby state.

Therefore, when the present embodiment is used, the resonance frequency of the quantum bit can be switched at high speed, the fidelity when the Rx/Ry computation is performed by applying the RF signal can be maintained high, and the QBA with higher computation accuracy than the conventional QBA and the quantum computer including the QBA can be provided.

### Fourth Embodiment

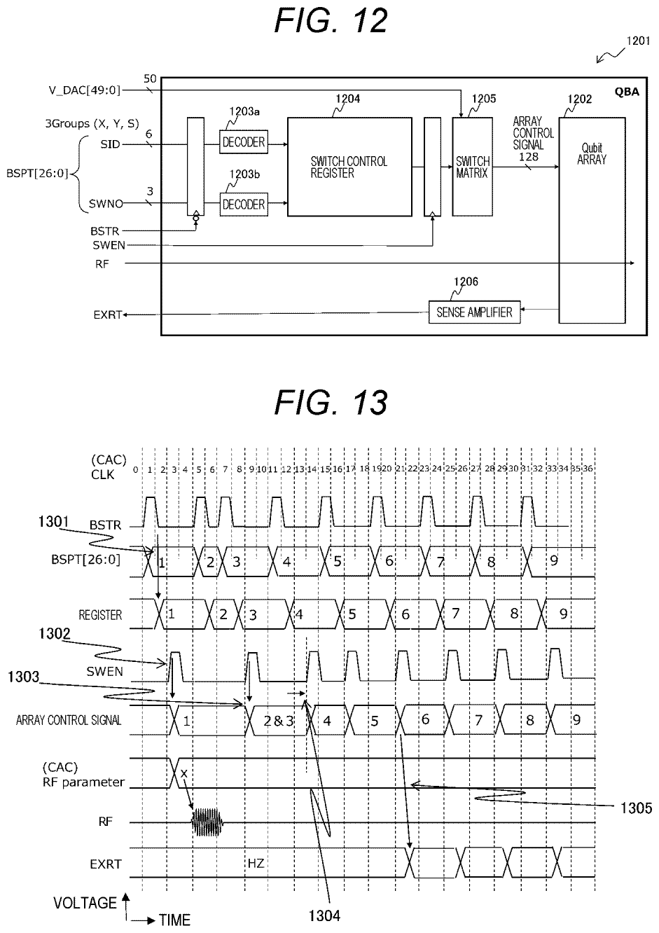

In order to describe a switch matrix switch control register configuration that realizes the supply of a plurality of bias voltage to a large number of quantum bit array control lines, which is a second object of the present invention, a configuration of a QBA is illustrated in FIG. 12.

50 types of array bias voltages V_DAC are supplied from the CAC to the QBA1201. To control how this bias voltage is applied to the respective quantum bit array control lines in the Qubit array 1202, the signal BSPT and the strobe signal BSTR are input to the QBA1201. In the QBA1201, a combination of a quantum bit array control line and a control voltage is defined by a total of 9-bit signals of a 6-bit control line address SID and a 3-bit control line voltage SWNO. The bias pattern signal BSPT enables simultaneous input of three pieces of control line information by a total of 27 signals of three groups X, Y, and S indicated by the control line address SID of the quantum bit array control line.

These pieces of information are decoded by the decoders 1203a and 1203b, respectively, and then held in the switch control register 1204, and the switch matrix 1205 is switched on the basis of the state of the switch control register 1204, and a desired bias voltage is output to the quantum bit array control line. This timing is defined by the control signal enable SWEN.

The RF signal for quantum computation is input from the RF and then propagated on the wire on the Qubit array 1202. The result of performing the quantum computation in the Qubit array 1202 is converted into classical digital information by the sense amplifier 1206 and output to the CAC via EXRT.

An example of a timing chart is illustrated in FIG. 13 in order to describe a signal interface system that defines the operation of the QBA. The CAC outputs a bias pattern signal BSPT in accordance with the system clock CLK and outputs a strobe signal BSTR for controlling the output timing of the bias pattern. In the QBA1201, the bias pattern signal BSPT is latched and decoded at the falling edge of the strobe signal BSTR, and then stored in the switch control register 1204 in the QBA1201. In the switch matrix 1205 which is an analog matrix switch, a voltage selected from the bias voltage V_DAC is connected to the quantum bit array control line, and this timing is defined by the control signal enable SWEN. Here, it is illustrated that the pattern 1 input by the clock 2 is output 1301 to the switch control register 1204 and output 1302 as an array control signal by the clock 3. For a quantum bit array control line to which information is not input at the timing when the strobe signal BSTR is input at this time, the previously set bias voltage is continuously output from the switch matrix 1205.

The number of patterns of control signals that can be input in one cycle is three at the maximum, and in order to change three or more control signals, it is necessary to update the switch control register 1204 in a plurality of cycles. Here, the control patterns 2 and 3 input by the clocks 6 and 8 are output 1303 as the array control signal by the control signal enable SWEN activated by the clock 9. The control signal enable SWEN can also be used to transition the control signal at timing independent of the system clock. An example in which the control pattern 4 input by the clock 12 is output 1304 as the array control signal at finely adjusted timing has been described.

As described above, by supplying the information of the bias voltage applied to a large number of quantum bit array control lines to the QBA1201 in a time division manner, the number of input signals of the QBA1201 can be limited. In a case where 8 types of bias voltages are assigned to each of the 128 array control signals and all combinations are input from the outside of the chip, 1000 or more signals are required, but in this configuration, only a total of 29 bias pattern signals BSPT27, strobe signals BSTR, and control signal enable SWEN2 are required.

Further, by inputting the strobe signal BSTR and the control signal enable SWEN that define the operation timing of the internal circuit of the QBA1201 from the CAC, the timing generation circuit can be omitted in the QBA, so that the power consumption of the QBA can be reduced.

The RF signal is applied from the RFQB at a timing specified in the CAC, and is used for computation processing of Qubit. The computation result is read 1305 from the data output terminal EXRT by inputting the sense amplifier control signal patterns 6 to 9 to the clocks 20 to 32.

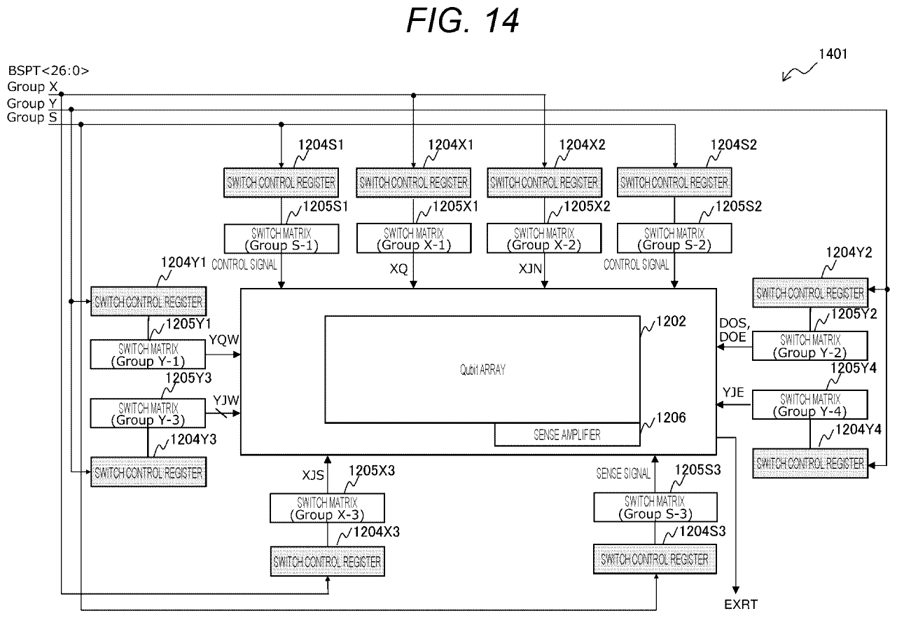

The main circuits used in the Qubit array are illustrated in FIG. 14. In FIG. 14, the circuit is configured as a resister switch block 1401 including a switch control register 1204 and a switch matrix 1205 for generating an array control signal, and the switch control register 1204 and the switch matrix 1205 are grouped for each signal and arranged around the Qubit array 1202 and the sense amplifier 1206.

The bias pattern signal BSPT is divided into Groups X, Y, and S, and is input to register groups corresponding to the respective Groups X, Y, and S. The signal of Group X is supplied to the switch control register 1204 (switch control registers 1204X1, 1204X2, and 1204X3) corresponding to a switch (Group X-1) that outputs the array signal XQ, a switch (Group X-2) that outputs the array signal XJN, and a switch (Group X-3) that outputs the array signal XJS. The signal of Group Y is supplied to a switch control register 1204 (switch control registers 1204Y1, 1204Y2, and 1204Y3) corresponding to a switch (Group Y-1) that outputs the array signal YQW, a switch (Group Y-2) that outputs the array signals DOS and DOE, a switch (Group Y-3) that outputs the array signal YJW, and a switch (Group Y-4) that outputs the array signal YJE. A signal of Group S is supplied to a switch control register 1204 (switch control registers 1204S1, 1204S2, 1204S3) corresponding to a switch (Group S-1, Group S-2) that outputs a control signal and a switch (Group S-3) that outputs a sense signal.

By grouping and dispersedly arranging the quantum bit array control lines in this manner, the connection between the switch matrix 1205 and the array control signal is facilitated. In addition, by dividing the bias pattern signal BSPT into three groups of X, Y, and S, information of three sets of quantum bit array control lines can be simultaneously updated, and the time required for setting the bias voltage can be shortened.

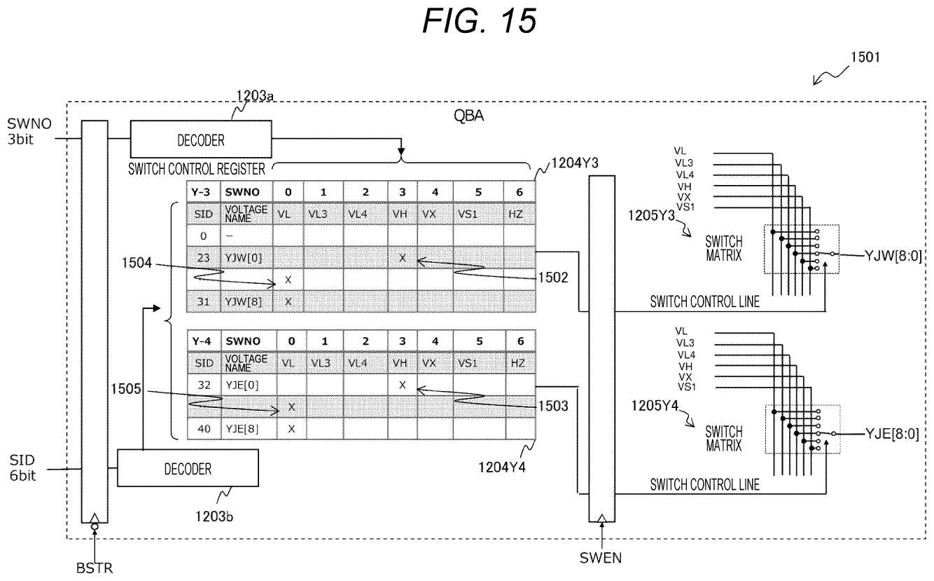

As an example, the configuration of the switch control register 1204 and the switch matrix 1205 of Groups Y-3 and Y-4 is illustrated in FIG. 15. The register switch block 1501 constitutes a switch matrix 1205 of 6:1 in which six types of bias voltages such as bias voltages V_{L} and V_{L3} are connected to 18 quantum bit array control lines of YJW[8, 7, . . . ] and YJE[8, 7, . . . ]. As illustrated in the drawing, a 6-bit SID is allocated to each control line.

When the bias pattern signal BSPT is input from the CAC and taken into the QBA by the strobe signal BSTR, the control line address SID and the control line voltage SWNO corresponding to each of Group X, Y, and S are decoded, and bits of the bias voltage to be output are held in the switch control register 1204 of the corresponding quantum bit array control line. In the drawing, YJW[0] and YJE[0] are set to output VH 1502 and 1503, and the other YJW[1] to YJW[8] and YJE[1] to YJE[8] are set to output VL 1503. Here, in a case where it is desired to rewrite only the control signals of Group X and S, when SID=0 of Group X is input, the switch control register 1204 is regarded as non-selected, and the register is not written. When the bit corresponding to the HZ is held, all the switches of the quantum bit array control line are turned off to enter the high impedance state.

When the control signal enable SWEN is input from the CAC, the contents of the switch control register 1204 are output to the switch matrix 1205, the switches of the corresponding control lines a are switched, and predetermined bias voltage is output to the array control signal.

As described above, by holding the information of the bias voltage applied to a large number of quantum bit array control lines in the switch control register 1204 and rewriting the information in a time division manner, there is an effect that the number of input signals of the QBA can be reduced. Further, by inputting the strobe signal BSTR and the control signal enable SWEN that define the operation timing of the QBA internal circuit from the CAC, the timing generation circuit can be omitted in the QBA, so that the power consumption of the QBA can be reduced.

As described above, in order to realize the supply of a plurality of bias voltages to a large number of quantum bit control lines, which is the second problem, the inventors have devised a switch matrix switch control register configuration, and have made it possible to store information on a correspondence relationship between a control line and a bias voltage in a switch control register, switch a switch matrix according to the content in the register, and supply a desired bias voltage to the quantum bit control lines. As a result, it is possible to supply a plurality of bias voltages to a large number of quantum bit control lines and to speed up the processing.

Hereinbefore, each embodiment has been described. As described above with reference to FIGS. 8A and 8B and the like, for example, a quantum bit array chip according to an aspect of the present invention includes a semiconductor layer, an insulating layer disposed on the semiconductor layer, a plurality of first gate electrodes (for example, the quantum dot control gate XQ) disposed on the insulating layer and trapping electrons in a predetermined spin state in the semiconductor layer by applying a voltage, a plurality of second gate electrodes (for example, the interaction control gate XJ) disposed alternately with the first gate electrodes adjacent to the first gate electrodes in order to cause a current for forming a magnetic field acting on the electrons to flow in an extending direction of the first gate electrodes when the spin state of the electrons is changed, and a third gate electrode (for example, the dummy quantum bit control gate of the dummy path 8012 in the X direction) having substantially the same resistance as the second gate electrodes, and when the spin state of electrons trapped in the first gate electrodes is changed, control is performed to cause a current to flow to the third gate electrode, and after the current is stabilized, stop the flowing of the current to the third gate electrode and cause a current to flow to the second gate electrodes.

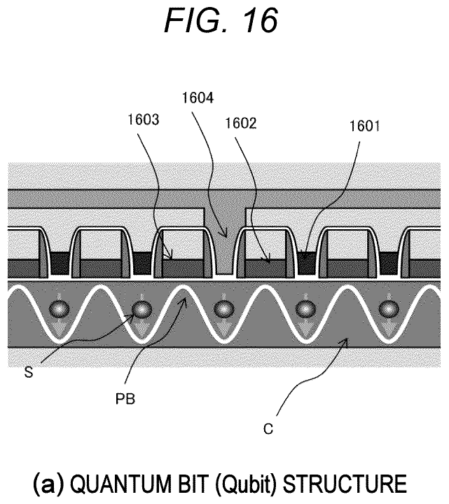

In addition, the third gate electrode in the dummy gate has the same structure as the second gate electrode, and a fourth gate electrode (for example, in FIG. 16, the gate 1604 in a case where there are the quantum dot control gate XQ1601, the interaction control gate XJ1602, and the dummy quantum bit control gate 1603 of the dummy path 8012) arranged adjacent to the third gate electrode has the same structure as the first gate electrode, and control is performed so as not to use electrons trapped under the fourth gate electrode for quantum computation in accordance with an instruction from the outside (for example, CAC803) of the quantum bit array chip.

Further, a first current switch (for example, the current switch SW₀) is connected to one of the second gate electrode, a second current switch (for example, the current switch SE₀) is connected to the other of the second gate electrode, a third current switch (for example, the current switch SW_{D}) is connected to one of the third gate electrode, a fourth current switch (for example, the current switch SE_{D}) is connected to the other of the third gate electrode, a terminal on a side opposite to a terminal connected to the gate electrodes of the first current switch and the third current switch is connected to a first common terminal (for example, the voltage supply node NW), a terminal on a side opposite to a terminal connected to the gate electrodes of the second current switch and the fourth current switch is connected to a second common terminal (for example, the voltage supply node NE), a current is supplied to the first common terminal from the outside (for example, CAC803) of the quantum bit array chip via a wire, and a current flows from the second common terminal to the outside of the quantum bit array chip via a wire.

The quantum bit array chip further includes a plurality of fifth gate electrodes (for example, the interaction control gate YJ) disposed above the first gate electrodes and the second gate electrodes in a stacking direction with an insulating film interposed therebetween and extending in a direction orthogonal to the first gate electrodes and the second gate electrode, and a sixth gate electrode (for example, the dummy quantum bit control gate of the dummy path 8012 in the Y direction) having substantially the same resistance as the fifth gate electrode, in which when a spin state of electrons trapped in the first gate electrodes is changed, control is performed to cause a current to flow to the sixth gate electrode and after the current is stabilized, stop the flowing of the current to the sixth gate electrode and cause a current to flow to the fifth gate electrode.

In addition, the fifth gate electrode has the same structure as the sixth gate electrode, and control is performed so as not to use electrons trapped under the sixth gate electrode (for example, the dummy quantum bit control gate 1603 in the Y direction) in the stacking direction for quantum computation in accordance with an instruction from the outside of the quantum bit array chip.

Further, a fifth current switch (for example, the current switch SW₀) is connected to one of the fifth gate electrode, a sixth current switch (for example, the current switch SE₀) is connected to the other of the fifth gate electrode, a seventh current switch (for example, the current switch SW_{D}) is connected to one of the sixth gate electrode, an eighth current switch (for example, the current switch SE_{D}) is connected to the other of the fifth gate electrodes, a terminal on a side opposite to a terminal connected to the gate electrodes of the fifth current switch and the seventh current switch is connected to a third common terminal (for example, the voltage supply node NW), a terminal on a side opposite to a terminal connected to the gate electrodes of the sixth current switch and the eighth current switch is connected to a fourth common terminal (for example, the voltage supply node NE), a current is supplied to the third common terminal from the outside (for example, CAC803) of the quantum bit array chip via a wire, and a current flows from the fourth common terminal to the outside of the quantum bit array chip via a wire.

Further, as described with reference to FIG. 9 and the like, a quantum bit array chip includes a semiconductor layer, an insulating layer disposed on the semiconductor layer, a plurality of first gate electrodes (for example, the quantum dot control gate XQ) disposed on the insulating layer and trapping electrons in a predetermined spin state in the semiconductor layer by applying a voltage, a plurality of second gate electrodes (for example, the interaction control gate XJ) disposed alternately with the first gate electrodes adjacent to the first gate electrodes, and a plurality of third gate electrodes (for example, the dummy path 9012) that strengthens a magnetic field acting on the electrons by causing currents in different directions to flow to a first direction second gate electrode (for example, gate 9011a connecting YJW₀ and YJE₀) and a second direction second gate electrode (for example, the gate 9011b connecting YJW₁ and YJE₁), which are two second gate electrodes adjacent to the first gate electrode, when the spin state of the electrons is changed, and have substantially the same resistance as the second gate electrodes, in which when the spin state of the electrons trapped in the first gate electrodes is changed, control is performed to cause a current to flow to a first direction third gate electrode (for example, the quantum bit control gate 9012a connecting the end YJW_{D0} and the end YJE_{D0}) and a second direction third gate electrode (for example, the quantum bit control gate 9012a connecting the end YJW_{D1} and the end YJE_{D1}), which are the two third gate electrodes, and after the current is stabilized, stop the flowing of the current to the third gate electrode and cause currents in different directions to flow to the two first direction second gate electrode and second direction second gate electrode.

In addition, the third gate electrode has the same structure as the second gate electrode, and a fourth gate electrode (for example, in FIG. 16, the gate 1604 in a case where there are the quantum dot control gate XQ1601, the interaction control gate XJ1602, and the dummy quantum bit control gate 1603 of the dummy path 8012) disposed adjacent to the third gate electrode has the same structure as the first gate electrode, and control is performed so as not to use electrons trapped under the fourth gate electrode for quantum computation according to an instruction from the outside of the quantum bit array chip.

Further, a first current switch (for example, the current switches SW_{0A} and SW_{0B}) is connected to one of the first direction second gate electrode, a second current switch (for example, the current switches SE_{0A} and SE_{0B}) is connected to the other of the first direction second gate electrode, a third current switch (for example, the current switches SW_{1A} and SW_{1B}) is connected to one of the second direction second gate electrode, a fourth current switch (for example, the current switches SE_{1A} and SE_{1B}) is connected to the other of the second direction second gate electrode, a fifth current switch (for example, the current switch SW_{D0}) is connected to one of the first direction third gate electrode, a sixth current switch (for example, the current switch SE_{D0}) is connected to the other of the first direction third gate electrode, a seventh current switch (for example, the current switch SW_{D1}) is connected to one of the second direction third gate electrode, an eighth current switch (for example, the current switch SE_{D1}) is connected to the other of the second direction third gate electrode, a terminal on a side opposite to terminals connected to gate electrodes of the first current switch and the fifth current switch is connected to a first common terminal (for example, the voltage supply node NW3), a terminal opposite to terminals connected to gate electrodes of the third current switch and the seventh current switch is connected to a second common terminal (for example, the voltage supply node NW4), a terminal opposite to terminals connected to gate electrodes of the second current switch and the sixth current switch is connected to a third common terminal (for example, the voltage supply node NE3), a terminal opposite to terminals connected to gate electrodes of the fourth current switch and the eighth current switch is connected to a fourth common terminal (for example, the voltage supply node NE4), a current is supplied to the first common terminal and the third common terminal from the outside (for example, CAC803) of the quantum bit array chip via a wire, and a current flows from the second common terminal and the fourth common terminal to the outside of the quantum bit array chip via a wire.

In addition, as described with reference to FIG. 10 and the like, a quantum bit computer includes a quantum bit array including a semiconductor layer, an insulating layer disposed on the semiconductor layer, a plurality of first gate electrodes (for example, the quantum dot control gate XQ) that are disposed on the insulating layer and trap electrons in a predetermined spin state in the semiconductor layer by applying a voltage, and a plurality of second gate electrodes (for example, the interaction control gate XJ) arranged alternately with the first gate electrodes adjacent to the first gate electrodes in order to cause a current for forming a magnetic field acting on the electrons to flow in an extending direction of the first gate electrodes when the spin state of the electrons is changed, a first chip (for example, QBA1101) on which the quantum bit array is mounted, a second chip that controls the first chip, and a cable that connects the first chip and the second chip (for example, CAC1103), in which when a current is supplied from a voltage output buffer (for example, the output buffer end NW₁) of the second chip to the second gate electrode of the quantum bit array included in the first chip, the voltage output buffer outputs a first voltage (for example, the voltage V_{L3I} in FIG. 11B) in a standby state, outputs a second voltage (for example, the voltage V_{L3O} in FIG. 11B) at an initial stage of supplying the current, and outputs a third voltage (for example, the voltage V_{L3} in FIG. 11B) that is substantially the same voltage as the first voltage when the current is stabilized.

With such a configuration, it is possible to switch the resonance frequency of the quantum bit at high speed, and it is possible to maintain high fidelity when computing rotation around the X axis and rotation around the Y axis, which are types of quantum computations.

Furthermore, as described with reference to FIGS. 12 and 15 and the like, a quantum bit array chip includes a semiconductor layer, an insulating layer disposed on the semiconductor layer, a plurality of gate electrodes (for example, the quantum dot control gate YQ) that are disposed on the insulating layer and trap electrons in a predetermined spin state in the semiconductor layer by applying a voltage, a switch matrix (for example, the switch matrix 1205) that controls a voltage output to the gate electrodes according to a voltage supplied from an external chip (for example, CAC803), a bias voltage supply terminal SWEN that outputs the controlled voltage to the gate electrodes, and a register (for example, the switch control register 1204) for generating an array control signal for the quantum bit array chip, in which a bias voltage is supplied to the gate electrode from a plurality of the bias voltage supply terminals via the switch matrix, and a voltage to be supplied to each of the gate electrodes is selectable, and the register stores the supplied bias voltage and the gate electrode to which the bias voltage is supplied in association with each other.

Furthermore, as described with reference to FIGS. 13 and 15 and the like, a bias pattern signal BSPT for controlling how to apply the bias voltage to the quantum bit array chip, a strobe signal BSTR for controlling an output timing of the bias pattern signal, and a control enable signal SWEN for controlling a timing to output a desired bias voltage by switching the switch matrix on the basis of a state of the register are input from the outside of the quantum bit array chip, the bias pattern signal is taken into the quantum bit array chip by the strobe signal, and the register is updated, and a desired bias voltage is output to the gate electrode by switching connection of the switch matrix according to a value of the register by the control enable signal.

Further, the bias pattern signal includes a control line address SID of a quantum bit array control line and a bias voltage SWNO applied to the quantum bit array control line of the control line address, and one of the registers is selected from among the plurality of registers according to the control line address decoded by a decoder 1203a, and a bit of one of the registers is activated according to the bias voltage decoded by the decoder 1203b.

Furthermore, as described with reference to FIG. 14 and the like, the decoder and the register are configured by a plurality of groups (for example, groups X, Y, and S corresponding to register groups), and the bias voltages to the plurality of gate electrodes can be set at a time at the same timing by inputting the bias pattern signals corresponding to the respective groups at the same timing.

With such a configuration, it is possible to reduce the number of input terminals of the chip and to speed up the processing, while enabling a plurality of bias voltages to be supplied to a large number of quantum bit control lines.

Note that the present invention is not limited to the above embodiments, and various modifications can be made within the scope of the gist of the present invention.

### REFERENCE SIGNS LIST

801, 901, 1101, 1201 QBA (quantum bit array chip)
803, 1103 CAC (cryogenic control chip)
8011, 9011, 1202 Qubit array
8012, 9012 dummy path
1203 decoder
1204 switch control register
1205 switch matrix
1206 sense amplifier
f_{S} spin precession frequency
E_{RF} RF signal frequency
φ_{RF} RF-reference phase difference
φ_{S} spin-reference phase difference
t_{R}, t_{RD}, T_{R0} signal stabilization time
V_{L3}, V_{L4} bias voltage
SW, SE switch
R_{W} cable parasitic resistance
C_{W} cable parasitic capacitance
R_{S} switch parasitic resistance
R_{Q} in-array gate parasitic resistance
t_{RB} rabbi oscillation period
I₀, I₁ quantum bit array current
I_{D}, I_{D0}, I_{D1} current dummy path current
NW, NE in-chip current supply node
V_DAC bias voltage
BSPT bias pattern signal
SID control line address
SWNO control line voltage
BSTR biaspartane strobe
SWEN control signal enable
EXRT computation result output

1. A quantum bit array chip comprising:
a semiconductor layer;
an insulating layer disposed on the semiconductor layer;
a plurality of first gate electrodes that are arranged on the insulating layer and trap electrons in a predetermined spin state in the semiconductor layer by applying a voltage;
a plurality of second gate electrodes arranged alternately with the first gate electrodes adjacent to the first gate electrodes in order to cause a current for forming a magnetic field acting on the electrons to flow in an extending direction of the first gate electrodes when the spin state of the electrons is changed; and
a third gate electrode having substantially the same resistance as the second gate electrodes,
wherein when the spin state of electrons trapped in the first gate electrodes is changed, control is performed to cause a current to flow to the third gate electrode, and after the current is stabilized, stop the flowing of the current to the third gate electrode and cause a current to flow to the second gate electrodes.

2. The quantum bit array chip according to claim 1, wherein the third gate electrode has the same structure as the second gate electrode,
a fourth gate electrode disposed adjacent to the third gate electrode has the same structure as the first gate electrode, and
control is performed so as not to use electrons trapped under the fourth gate electrode for quantum computation in accordance with an instruction from the outside of the quantum bit array chip.

3. The quantum bit array chip according to claim 2, wherein
a first current switch is connected to one of the second gate electrode, and a second current switch is connected to the other of the second gate electrode,
a third current switch is connected to one of the third gate electrode, and a fourth current switch is connected to the other of the third gate electrode,
a terminal on a side opposite to terminals connected to gate electrodes of the first current switch and the third current switch is connected to a first common terminal,
a terminal opposite to terminals connected to gate electrodes of the second current switch and the fourth current switch is connected to a second common terminal,
a current is supplied to the first common terminal from the outside of the quantum bit array chip via a wire, and
a current flows from the second common terminal to the outside of the quantum bit array chip via a wire.

4. The quantum bit array chip according to claim 1, further comprising:
a plurality of fifth gate electrodes disposed above the first gate electrodes and the second gate electrodes in a stacking direction with an insulating film interposed therebetween and extending in a direction orthogonal to the first gate electrodes and the second gate electrode; and
a sixth gate electrode having substantially the same resistance as the fifth gate electrode,
wherein when a spin state of electrons trapped in the first gate electrodes is changed, control is performed to cause a current to flow to the sixth gate electrode and after the current is stabilized, stop the flowing of the current to the sixth gate electrode and cause a current to flow to the fifth gate electrode.

5. The quantum bit array chip according to claim 4, wherein
the fifth gate electrode has the same structure as the sixth gate electrode, and
control is performed so as not to use electrons trapped under the sixth gate electrode in the stacking direction for quantum computation in accordance with an instruction from the outside of the quantum bit array chip.

6. The quantum bit array chip according to claim 5, wherein
a fifth current switch is connected to one of the fifth gate electrode, and a sixth current switch is connected to the other of the fifth gate electrode,
a seventh current switch is connected to one of the sixth gate electrode, and an eighth current switch is connected to the other of the sixth gate electrode,
a terminal on a side opposite to terminals connected to gate electrodes of the fifth current switch and the seventh current switch is connected to a third common terminal,
a terminal on a side opposite to terminals connected to gate electrodes of the sixth current switch and the eighth current switch is connected to a fourth common terminal,
a current is supplied to the third common terminal from the outside of the quantum bit array chip via a wire, and
a current flows from the fourth common terminal to the outside of the quantum bit array chip via a wire.

7. A quantum bit array chip comprising:
a semiconductor layer;
an insulating layer disposed on the semiconductor layer;
a plurality of first gate electrodes that are arranged on the insulating layer and trap electrons in a predetermined spin state in the semiconductor layer by applying a voltage;
a plurality of second gate electrodes arranged alternately with the first gate electrodes adjacent to the first gate electrodes; and
a plurality of third gate electrodes that strengthens a magnetic field acting on the electrons by causing currents in different directions to flow to a first direction second gate electrode and a second direction second gate electrode, which are two second gate electrodes adjacent to the first gate electrode, when the spin state of the electrons is changed, and have substantially the same resistance as the second gate electrodes,
wherein when the spin state of the electrons trapped in the first gate electrodes is changed, control is performed to cause a current to flow to a first direction third gate electrode and a second direction third gate electrode, which are the two third gate electrodes, and after the current is stabilized, stop the flowing of the current to the third gate electrode and cause currents in different directions to flow to the two first direction second gate electrode and second direction second gate electrode.

8. The quantum bit array chip according to claim 7, wherein
the third gate electrode has the same structure as the second gate electrode,
a fourth gate electrode disposed adjacent to the third gate electrode has the same structure as the first gate electrode, and
control is performed so as not to use electrons trapped under the fourth gate electrode for quantum computation in accordance with an instruction from the outside of the quantum bit array chip.

9. The quantum bit array chip according to claim 8, wherein
a first current switch is connected to one of the first direction second gate electrode, and a second current switch is connected to the other of the first direction second gate electrode,
a third current switch is connected to one of the second direction second gate electrode, and a fourth current switch is connected to the other of the second direction second gate electrode,
a fifth current switch is connected to one of the first direction third gate electrode, and a sixth current switch is connected to the other of the first direction third gate electrode,
a seventh current switch is connected to one of the second direction third gate electrode, and an eighth current switch is connected to the other of the second direction third gate electrode,
a terminal on a side opposite to terminals connected to gate electrodes of the first current switch and the fifth current switch is connected to a first common terminal,
a terminal opposite to terminals connected to gate electrodes of the third current switch and the seventh current switch is connected to a second common terminal,
a terminal opposite to terminals connected to gate electrodes of the second current switch and the sixth current switch is connected to a third common terminal,
a terminal opposite to terminals connected to gate electrodes of the fourth current switch and the eighth current switch is connected to a fourth common terminal,
a current is supplied to the first common terminal and the third common terminal from the outside of the quantum bit array chip via a wire, and
a current flows from the second common terminal and the fourth common terminal to the outside of the quantum bit array chip via a wire.

10. A quantum bit computer comprising:
a quantum bit array including a semiconductor layer, an insulating layer disposed on the semiconductor layer, a plurality of first gate electrodes that are disposed on the insulating layer and trap electrons in a predetermined spin state in the semiconductor layer by applying a voltage, and a plurality of second gate electrodes arranged alternately with the first gate electrodes adjacent to the first gate electrodes in order to cause a current for forming a magnetic field acting on the electrons to flow in an extending direction of the first gate electrodes when the spin state of the electrons is changed;
a first chip on which the quantum bit array is mounted;
a second chip that controls the first chip; and
a cable that connects the first chip and the second chip,
wherein when a current is supplied from a voltage output buffer of the second chip to the second gate electrode of the quantum bit array included in the first chip, the voltage output buffer outputs a first voltage in a standby state, outputs a second voltage at an initial stage of supplying the current, and outputs a third voltage that is substantially the same voltage as the first voltage when the current is stabilized.

11. A quantum bit array chip comprising:
a semiconductor layer;
an insulating layer disposed on the semiconductor layer;
a plurality of gate electrodes that are disposed on the insulating layer and trap electrons in a predetermined spin state in the semiconductor layer by applying a voltage;
a switch matrix that controls a voltage output to the gate electrodes according to a voltage supplied from an external chip;
a bias voltage supply terminal that outputs the controlled voltage to the gate electrodes; and
a register for generating an array control signal for the quantum bit array chip,
wherein a bias voltage is supplied to the gate electrode from a plurality of the bias voltage supply terminals via the switch matrix, and
a voltage to be supplied to each of the gate electrodes is selectable, and the register stores the supplied bias voltage and the gate electrode to which the bias voltage is supplied in association with each other.

12. The quantum bit array chip according to claim 11, wherein
a bias pattern signal for controlling how to apply the bias voltage to the quantum bit array chip, a strobe signal for controlling an output timing of the bias pattern signal, and a control enable signal for controlling a timing to output a desired bias voltage by switching the switch matrix on the basis of a state of the register are input from the outside of the quantum bit array chip,
the bias pattern signal is taken into the quantum bit array chip by the strobe signal, and the register is updated, and
a desired bias voltage is output to the gate electrode by switching connection of the switch matrix according to a value of the register by the control enable signal.

13. The quantum bit array chip according to claim 12, wherein
the bias pattern signal includes a control line address of a quantum bit array control line and a bias voltage applied to the quantum bit array control line of the control line address,
one of the registers is selected from among the plurality of registers according to the control line address decoded by a decoder, and
a bit of one of the registers is activated according to the bias voltage decoded by the decoder.

14. The quantum bit array chip according to claim 13, wherein
the decoder and the register are configured by a plurality of groups, and
the bias voltages to the plurality of gate electrodes can be set at a time at the same timing by inputting the bias pattern signals corresponding to the respective groups at the same timing.
